(19) United States
(12) Patent Application Publication
(10) Pub. No.: US 2012/0161131 A1
(43) Pub. Date: Jun. 28, 2012

(54) THIN-FILM TRANSISTOR SUBSTRATE AND METHOD OF MANUFACTURING THE SAME

(75) Inventors: Min KANG, Seoul (KR); Chong-Sup CHANG, Hwaseong-si (KR); Hyeong-Suk YOO, Yongin-si (KR); Jin-Ho JU, Seoul (KR)

(73) Assignee: SAMSUNG ELECTRONICS CO., LTD., Suwon-si (KR)

(21) Appl. No.: 13/216,326

(22) Filed: Aug. 24, 2011

(30) Foreign Application Priority Data
Dec. 28, 2010 (KR) 10-2010-0137067

(51) Int. Cl. H01L 29/786; H01L 21/28

(52) U.S. Cl. 257/57; 257/66; 438/585; 257/E29.273; 257/E21.19

(57) ABSTRACT

A thin-film transistor (“TFT”) substrate includes a metal wiring including copper or a copper alloy on a substrate, an inorganic layer on an upper surface and side surfaces of the metal wiring to surround the metal wiring, the inorganic layer in direct contact with the metal wiring, and a planarization layer on the inorganic layer and in direct contact with the inorganic layer.

This application claims priority to Korean Patent Application No. 10-2010-0137067 filed on Dec. 28, 2010, and all the benefits accruing therefrom under 35 U.S.C. §119, the disclosure of which is incorporated herein by reference in its entirety.

### BACKGROUND OF THE INVENTION

1. Field of the Invention

The present invention relates to a thin-film transistor (“TFT”) substrate employing a low resistance wiring, and a method of manufacturing the TFT substrate.

2. Description of the Related Art

As liquid crystal displays (“LCDs”) and organic light-emitting diodes (“OLEDs”) are increasingly becoming larger in size and higher in resolution, the scan time is reduced while the speed of signal processing is increased. To cope with the reduced scan time and the increased speed of signal processing, a low resistance wiring is essential in such LCDs and OLEDs.

To realize a low resistance wiring, the thickness of a metal wiring is increased. However, an increase in the thickness of the metal wiring results in an increase in a height of a gate electrode in a thin-film transistor (“TFT”), risking a short circuit between a source electrode and a drain electrode that are formed on the gate electrode.

While aluminum (Al) or an aluminum alloy has been primarily used to form a metal wiring, the Al or alloy thereof is being replaced by copper that exhibits superior resistivity properties and electromigration properties. However, a problem lies in the fact that copper readily diffuses to an insulating layer or an active layer even at a relatively low temperature. Therefore, it is difficult to use copper to form a metal wiring.

### BRIEF SUMMARY OF THE INVENTION

Aspects of the present invention provide a thin-film transistor (“TFT”) substrate in which the diffusion of copper can be reduced or effectively prevented when a low resistance wiring includes copper.

Aspects of the present invention also provide a method of manufacturing the TFT substrate.

However, aspects of the present invention are not restricted to the one set forth herein. The above and other aspects of the present invention will become more apparent to one of ordinary skill in the art to which the present invention pertains by referencing the detailed description of the present invention given below.

According to an exemplary embodiment of the present invention, there is provided a TFT substrate including a metal wiring including copper or a copper alloy on a substrate, an inorganic film on an upper surface and side surfaces of the metal wiring to surround the metal wiring, the inorganic film in direct contact with the metal wiring, and a planarization film on the inorganic film and in direct contact with the inorganic film.

According to another exemplary embodiment of the present invention, there is provided a method of manufacturing a TFT substrate. The method includes forming a metal wiring of copper or a copper alloy on a substrate, forming an inorganic film to be in direct contact with the metal wiring and to surround the metal wiring, forming an organic film including an organic material on the substrate, and planarizing the organic film by removing a predetermined portion of the organic film such that a maximum distance between a surface of the substrate and a top surface of the organic film is smaller than or equal to a maximum distance between the surface of the substrate and a top surface of the inorganic film.

### BRIEF DESCRIPTION OF THE DRAWINGS

The above and other aspects and features of the present invention will become more apparent by describing in detail exemplary embodiments thereof with reference to the attached drawings, in which:

FIG. 1 is a plan view of an exemplary embodiment of a thin-film transistor (“TFT”) substrate according to the present invention;

FIG. 2 is a cross-sectional view of the TFT substrate taken along line I-I′ of FIG. 1;

FIG. 3 is a cross-sectional view of another exemplary embodiment of a TFT substrate according to the present invention;

FIG. 4 is a cross-sectional view of still another exemplary embodiment of a TFT substrate according to the present invention;

FIG. 5 is a flowchart illustrating an exemplary embodiment of a method of manufacturing a TFT substrate according to the present invention; and

FIGS. 6 through 13 are cross-sectional views respectively illustrating exemplary embodiments of processes of the method of manufacturing a TFT substrate according to the present invention.

### DETAILED DESCRIPTION OF THE INVENTION

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, sizes and relative sizes of layers and regions may be exaggerated for clarity.

It will be understood that when an element or layer is referred to as being “on” another element or layer, the element or layer can be directly on another element or layer or intervening elements or layers may also be present. In contrast, when an element is referred to as being “directly on” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “above,” “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Like reference numerals refer to like elements throughout the specification.

Embodiments of the invention are described herein with reference to plan and cross-section illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, exemplary embodiments of the present invention will be described in further detail with reference to the accompanying drawings.

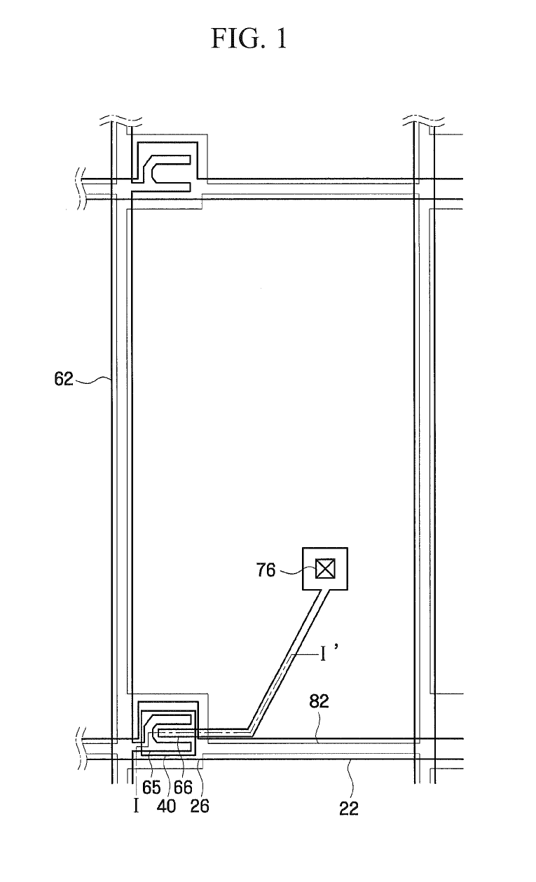

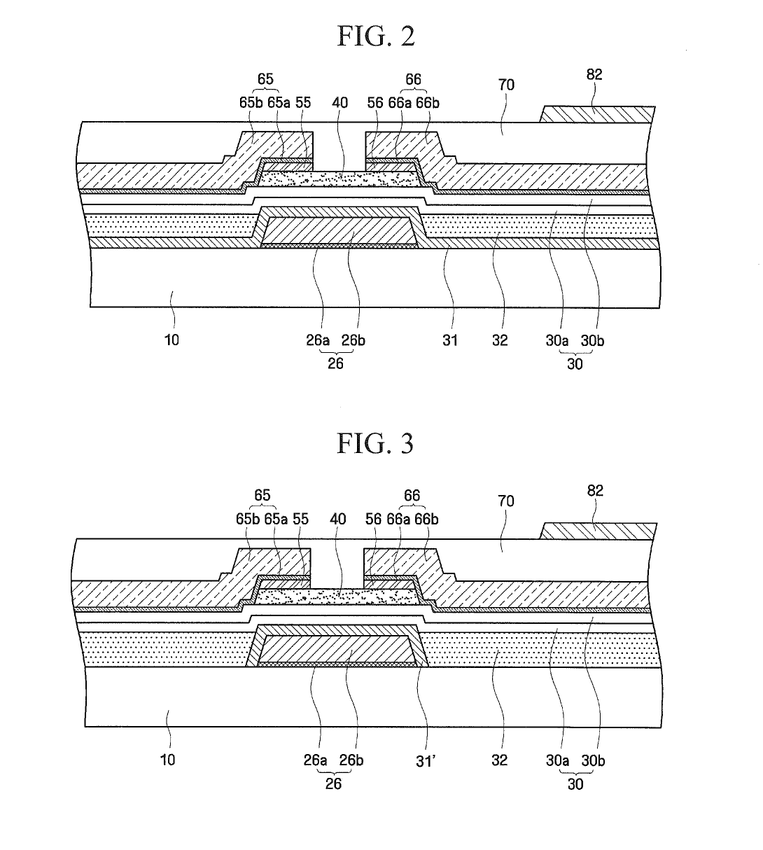

An exemplary embodiment of a thin-film transistor (“TFT”) substrate according to the present invention will now be described with reference to FIGS. 1 and 2.

FIG. 1 is a plan view of the exemplary embodiment of a TFT substrate according to the present invention. FIG. 2 is a cross-sectional view of the TFT substrate taken along line I-I′ of FIG. 1.

Referring to FIGS. 1 and 2, the TFT substrate according to the illustrated exemplary embodiment includes a gate electrode 26, a first inorganic layer 31, a first planarization layer 32, a first insulating layer 30 which may be referred to as a gate insulating layer, an active layer 40, ohmic contact layers 55 and 56, a source electrode 65, and a drain electrode 66. The TFT substrate may further include a passivation film 70 and a pixel electrode 82.

The gate electrode 26 is directly on an upper surface of the substrate 10, is physically and electrically connected to a gate line 22, and protrudes from the gate line 22.

The substrate 10 includes a transparent insulating material. The substrate 10 may be an insulating substrate including, e.g., glass or plastic.

The gate electrode 26 may include aluminum (Al)-based metal such as aluminum or an aluminum alloy, silver (Ag)-based metal such as silver or a silver alloy, copper (Cu)-based metal such as copper or a copper alloy, molybdenum (Mo)-based metal, such as molybdenum or a molybdenum alloy, chrome (Cr), titanium (Ti) or tantalum (Ta).

In addition, the gate electrode 26 may have a multi-film (layered) structure including two conductive films (not shown) with different physical characteristics. One of the two conductive films may include metal with low resistivity, such as aluminum-based metal, silver-based metal or copper-based metal, in order to reduce a signal delay or a voltage drop of the gate electrode 26. The other one of the conductive films may include a different material, in particular, a material having superior contact characteristics with indium tin oxide (“ITO”) and indium zinc oxide (“IZO”), such as molybdenum-based metal, chrome, titanium, or tantalum.

Exemplary embodiments of multi-film structures of the gate electrode 26 include a chrome lower film and an aluminum upper film, and an aluminum lower film and a molybdenum upper film. However, the present invention is not limited thereto. The gate electrode 26 may include various metals and conductors. Preferably, the gate electrode 26 may include a copper or copper alloy. Specifically, as shown in FIG. 2, the gate electrode 26 may include a copper upper layer 26b including copper or a copper alloy, and a titanium lower layer 26a disposed between the copper layer 26b and the substrate 10. The lower layer 26a in contact with the substrate 10 includes titanium that exhibits better contact characteristics than copper. Copper has superior resistivity properties and electromigration properties. Due to these properties, copper can reduce the resistive-capacitive (“RC”) delay.

The gate electrode 26 may have a thickness of about 5,000 angstroms (Å) or more. When the gate electrode 26 has the thickness of about 5,000 Å or more, resistance of the gate electrode 26 may be reduced. The reduced resistance may enable the realization of a low resistance wiring, but deteriorates step height characteristics of a TFT.

The first inorganic layer 31 may be directly on both the substrate 10 and the gate electrode 26. The first inorganic layer 31 may surround the gate electrode 26 and be in direct contact with the gate electrode 26. To surround the gate electrode 26, the first inorganic layer 31 contacts all of upper and side surfaces of the gate electrode 26. The first inorganic layer 31 not only surrounds the gate electrode 26, but also extends directly onto the substrate 10 on which the gate electrode 26 is not disposed, as shown in FIG. 2.

To form a low resistance wiring in order to reduce the RC delay, the gate electrode 26 may include copper or a copper alloy as described above. However, since copper is highly diffusive even at a low temperature, it may diffuse to the first insulating layer 30 and/or the active layer 40 without a barrier between the copper of the gate electrode 26, and the first insulating layer 30 and/or the active layer 40. However, in the illustrated embodiment, the first inorganic layer 31 reduces or effectively prevents the diffusion of copper when the gate electrode 26 includes copper. In order to block the diffusion of copper, the first inorganic layer 31 is in direct contact with the gate electrode 26, and between the gate electrode 26 and the first insulating layer 30, and/or between the gate electrode 26 and the active layer 40.

The first inorganic layer 31 may include an inorganic material such as silicon nitride (SiNx) or silicon oxide (SiO₂). Specifically, the first inorganic layer 31 may include silicon nitride.

The first inorganic layer 31 may have a thickness of about 200 Å to about 5,000 Å. In one exemplary embodiment, the first inorganic layer 31 may have a thickness of about 1,000 Å to about 5,000 Å. In the above thickness ranges, the first inorganic layer 31 can reduce or effectively prevent the diffusion of copper. As illustrated in FIG. 2, the first inorganic layer 31 includes a first portion parallel with the upper surface of the substrate 10 and overlapping the gate electrode 26, and a second portion continuous with the first portion, inclined with respect to the upper surface of the substrate 10 and contacting the upper surface of the substrate 10. The first inorganic layer 31 further includes a third portion parallel with the upper surface of the substrate 10 and not overlapping the gate electrode 26.

The first planarization layer 32 is on the first inorganic layer 31 and disposed on the entire surface of the substrate 10 to surround the first inorganic layer 31. The first planarization layer 32 may be in direct contact with the first inorganic layer 31. The first planarization layer 32 fills a portion of a space between the substrate 10 and a first insulating sub-layer 30a, which will be described later, thereby reducing step heights formed by the gate electrode 26 and the first inorganic layer 31.

Since the first planarization layer 32 serves to correct or reduce the step heights of the gate electrode 26 and the first inorganic layer 31, the first planarization layer 32 may have an upper surface that is coplanar with an upper surface of the first inorganic layer 31 overlapping the gate electrode 26. Alternatively, the upper surface of the first planarization layer 32 may have a height lower than that of the first inorganic layer 31 on the gate electrode 26 taken from the substrate 10. That is, a maximum distance between a surface of the substrate 10 and a top surface of the first planarization layer 32 may be equal to or smaller than a maximum distance between the surface of the substrate 10 and a top surface of the first inorganic layer 31.

To form a low resistance wiring in order to reduce the RC delay, the thickness of a metal wiring such as the gate electrode 26 is increased, which, in turn, increases a step height between the gate electrode 26 and the substrate 10. The increased step height causes a short circuit between the source electrode 65 and the drain electrode 66 which extend from above the gate electrode 26 downward onto the substrate 10. That is, when the metal wiring, e.g. gate electrode 26, is itself thicker than, e.g., the first insulating layer 30, the first insulating layer 30 being on the metal wiring may form an uneven surface with a large step height, thus causing an electrical short circuit. Therefore, the first planarization layer 32 is needed to correct the step height between the gate electrode 26 and the substrate 10. The step height reduced by the first planarization layer 32 reduces or effectively prevents a short circuit of the source and drain electrodes 65 and 66, which are above the gate electrode 26 relative to the substrate 10.

The first planarization layer 32 may include an organic layer including an organic material. An organic material exhibits better planarization properties than an inorganic material. Therefore, even when the gate electrode 26 has a relative large thickness, the first planarization layer 32 including an organic material can easily improve step height characteristics of the gate electrode 26. Specifically, the organic material may include a material or a mixture of materials selected from the group consisting of acryl, polyimide, and polyacrylimide. However, the present invention is not limited thereto, and any material known in the art can be used without impairing the objectives of the present invention.

The first insulating layer 30 may be on an entire surface of the substrate 10, to cover the first inorganic layer 31 and the first planarization layer 32. The first insulating layer 30 may include the first insulating sub-layer 30a directly on the first inorganic layer 31 and the first planarization layer 32, and a second insulating sub-layer 30b directly on the first insulating sub-layer 30a.

The first insulating sub-layer 30a is disposed on the first inorganic layer 31 and the first planarization layer 32, and may include an inorganic material, such as silicon nitride or silicon oxide, or a low-k insulating material formed by plasma enhanced chemical vapor deposition (“PECVD”), such as a-Si:C:O or a-Si:O:F.

In an exemplary embodiment, the first insulating sub-layer 30a may be formed by depositing an insulating material on the first inorganic layer 31 and the first planarization layer 32 at a first speed. The first insulating sub-layer 30a is formed at high speed to allow the first insulating layer 30 to have a predetermined thickness. Here, physical and electrical properties of the first insulating sub-layer 30a are not a large consideration.

The second insulating sub-layer 30b is directly on the first insulating sub-layer 30a. The second insulating sub-layer 30b may include a same or different material as the first insulating sub-layer 30a. Specifically, the second insulating sub-layer 30b may include an inorganic material such as silicon nitride or silicon oxide, an organic material having photosensitivity and superior planarization characteristics, or a low-k insulating material formed by PECVD, such as a-Si:C:O or a-Si:O:F.

In an exemplary embodiment, the second insulating sub-layer 30b may be formed by coating an insulating material on the first insulating sub-layer 30a at second speed which is lower than the first speed. The second insulating sub-layer 30b is in contact with the active layer 40 which will be described later. To improve physical and electrical properties (such as permittivity) of the second insulating sub-layer 30b in order to ultimately enhance properties of the TFT, the second insulating sub-layer 30b may be deposited at lower speed than the deposition speed of the first insulating sub-layer 30a. The second insulating sub-layer 30b increases the mobility of electrons in a channel of the TFT and reduces the amount of current leaked to the outside.

The active layer 40 is directly on the first insulating layer 30 and overlaps the gate electrode 26.

The active layer 40 may include hydrogenated amorphous silicon or polycrystalline silicon. The active layer 40 may have various shapes. In one exemplary embodiment, for example, the active layer 40 may be an island-shape or may be linearly shaped, in the plan view. In FIG. 2, the active layer 40 is island-shaped. As used herein, island-shape may indicate a separate discrete element, such as being surrounded by another element. The active layer 40 includes an exposed portion on which the ohmic contact layers 55 and 56, which will be described later, are not disposed. The exposed portion serves as a channel of the TFT through which electrons move.

The ohmic contact layers 55 and 56 are directly on the active layer 40 and are separated from each other with respect to the exposed portion of the active layer 40. The ohmic contact layers 55 and 56 include a material, such as silicide or n+ hydrogenated amorphous silicon heavily doped with n-type impurities.

The ohmic contact layers 55 and 56 are interposed between the active layer 40 and the source electrode 65, and between the active layer 40 and the drain electrode 66, to reduce contact resistance between them.

The ohmic contact layers 55 and 56 may have various shapes in the plan view. In one exemplary embodiment, for example, the ohmic contact layers 55 and 56 may be island-shaped or may be shaped linearly. When the ohmic contact layers 56 and 55 are island-shaped as shown in FIG. 2, they may be under the drain electrode 66 and the source electrode 65, respectively.

A data line 62 is on the ohmic contact layers 55 and 56, and on the first insulating layer 30. The data line 62 extends e.g., in a vertical direction and intersects the gate line 22. In an exemplary embodiment, the data line 62 and the gate line 22 intersecting each other may define a pixel or pixel region. The TFT substrate may include a plurality of pixels or pixel regions.

The source electrode 65 branches from the data line 62 and extends onto the semiconductor layer 40, and the ohmic contact layers 55 and 56. At least a portion of the source electrode 65 overlaps the active layer 40 and/or the ohmic contact layers 55 and 56.

The drain electrode 66 is on the ohmic contact layers 55 and 56, and on the first insulating layer 30. The drain electrode 66 is separated from the source electrode 65, and is disposed on the active layer 40 to face the source electrode 65 with respect to the gate electrode 26. The data line 62, the source electrode 65, and the drain electrode 66 are referred to as data wirings.

The data wirings (62, 65 and 66) may include chrome, molybdenum-based metal, or refractory metal such as tantalum or titanium. In addition, the data wirings (62, 65 and 66) may have a multi-layer structure including a lower layer (not shown), which includes refractory metal, and an upper layer (not shown), which includes a material with low resistance and is directly on the lower layer.

The source electrode 65 and the drain electrode 66 may include copper or a copper alloy. In one exemplary embodiment, each of the source electrode 65 and the drain electrode 66 includes a copper or copper alloy upper layer 65b and 66b, and a titanium lower layer 65a and 66a, respectively, for enhancing contact characteristics with the ohmic contact layer 55 and 56. When the source electrode 65 and the drain electrode 66 include copper or a copper alloy, they may have a thickness of about 5,000 Å or more. When the source and drain electrodes 65 and 66 have the thickness of 5,000 Å or more, the resistance of the wirings is reduced, resulting in a reduction in the RC delay.

The passivation layer 70 is on the source electrode 65, the drain electrode 66 and the exposed portion of the active layer 40, and includes an insulating layer. The passivation layer 70 may include an inorganic material such as silicon nitride or silicon oxide, an organic material having photosensitivity and superior planarization characteristics, or a low-k insulating material formed by PECVD, such as a-Si:C:O or a-Si:O:F. The passivation layer 70 may include a lower inorganic layer and an upper organic layer in order to protect the exposed portion of the active layer 40, while taking advantage of the superior characteristics of an organic layer. A contact hole 76 exposing the drain electrode 66 is extended completely through a thickness of the passivation layer 70.

The pixel electrode 82 is on the passivation layer 70, and is electrically connected to the drain electrode 66 by the contact hole 76 in each pixel. That is, the pixel electrode 82 is physically and electrically connected to the drain electrode 66 by the contact hole 76 and thus receives a data voltage from the drain electrode 66. The pixel electrode 82 may include a transparent conductor, such as ITO or IZO, or a reflective conductor such as aluminum. An alignment layer (not shown) for aligning liquid crystal molecules may be on the pixel electrode 82 and the passivation layer 70.

Hereinafter, another exemplary embodiment of a TFT substrate according to the present invention will be described with reference to FIG. 3. For simplicity, elements having the same functions as those of the exemplary embodiment illustrated in FIGS. 1 and 2 are indicated by like reference numerals, and thus their description will be omitted. FIG. 3 is a cross-sectional view of another exemplary embodiment of a TFT substrate according to the present invention. The TFT substrate shown in FIG. 3 is a modified example of the TFT substrate shown in FIG. 2.

Referring to FIG. 3, the TFT substrate according to the illustrated exemplary embodiment includes the gate electrode 26, a first inorganic layer 31′, the first planarization layer 32, the first insulating layer 30, the active layer 40, the ohmic contact layers 55 and 56, the source electrode 65, and the drain electrode 66. The TFT substrate according to the illustrated exemplary embodiment has basically the same structure as the TFT substrate according to the previous exemplary embodiment, except for the first inorganic layer 31′. Therefore, the following description will focus on the first inorganic layer 31′.

The first inorganic layer 31′ surrounds the gate electrode 26 and is in direct contact with the gate electrode 26. The first inorganic layer 31′ is considered not on a portion of the substrate 10 on which the gate electrode 26 is not disposed. As illustrated in FIG. 3, the first inorganic layer 31′ includes a first portion parallel with the upper surface of the substrate 10 and overlapping the gate electrode 26, and a second portion continuous with the first portion, inclined with respect to the upper surface of the substrate 10 and contacting the upper surface of the substrate 10. The first inorganic layer 31′ of the illustrated exemplary embodiment does not include a third portion as described with respect to the exemplary embodiment shown in FIG. 2, however, a portion of the second portion contacts the upper surface of the substrate 10 to complete the first inorganic layer 31′ surrounding the gate electrode 26.

When the gate electrode 26 includes copper or copper alloy in order to realize a low resistance wiring, the first inorganic layer 31′ reduces or effectively prevents the diffusion of copper to the first insulating layer 30 or the active layer 40. Thus, as long as the first inorganic layer 31′ surrounds the gate electrode 26, e.g., contacts all of the upper and the side surfaces of the gate electrode 26, it is not necessary to dispose the first inorganic layer 31′ on the portion of the substrate 10 on which the gate electrode 26 is not disposed.

The first planarization layer 32 is between the substrate 10 and the first insulating sub-layer 30a disposed directly on the first inorganic layer 31′. That is, the first planarization layer 32 between the substrate 10 and the first insulating sub-layer 30a on the first inorganic layer 31′, can reduce a step height formed by the gate electrode 26 and the first inorganic layer 31′.

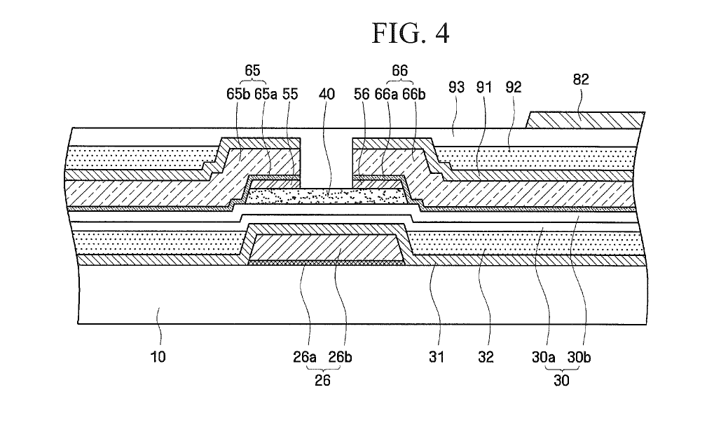

Hereinafter, still another exemplary embodiment of a TFT substrate according to the present invention will be described with reference to FIG. 4. FIG. 4 is a cross-sectional view of another exemplary embodiment of a TFT substrate according to the present invention.

Referring to FIG. 4, the TFT substrate according to the illustrated exemplary embodiment has the same elements and functions as the TFT substrate shown in FIGS. 1 and 2, except that a second inorganic layer 91, a second planarization layer 92, and a second insulating layer 93 are further on the source electrode 65 and the drain electrode 66. Therefore, the same elements are indicated by like reference numerals, and thus a detailed description thereof will be omitted. The following description will focus on the second inorganic layer 91, the second planarization layer 92, and the second insulating layer 93.

The source electrode 65 and the drain electrode 66 may include copper or a copper alloy. In one exemplary embodiment, each of the source electrode 65 and the drain electrode 66 may include a copper or copper alloy upper layer 65b and 66b, and a titanium lower layer 65a and 66a, respectively, to enhance contact characteristics of copper or a copper alloy with the ohmic contact layer 55 and 56.

Copper has superior resistivity properties and electromigration properties. Thus, when the source electrode 65 and the drain electrode 66 include copper or a copper alloy, the resistance of the wirings is reduced, resulting in a reduction in the RC delay.

The second inorganic layer 91 may be on an upper surface the source electrode 65 and the drain electrode 66. In FIG. 4, the second inorganic layer 91 is directly on the source electrode 65 and the drain electrode 66. However, the second inorganic layer 91 may also completely surround the source electrode 65 and the drain electrode 66. The second inorganic layer 91 directly contacts the source electrode 65 and the drain electrode 66.

When metal wirings such as the source electrode 65 and the drain electrode 66 include copper in order to reduce the RC delay, the copper may diffuse to, e.g., the second insulating layer 93, because copper is highly diffusive even at a low temperature. However, the second inorganic layer 91 reduces or effectively prevents the diffusion of copper.

The second inorganic layer 91 may include an inorganic material such as silicon nitride or silicon oxide. Specifically, the second inorganic layer 91 may include silicon nitride.

The second planarization layer 92 is on the inorganic layer 91 to be in direct contact with the second inorganic layer 91. The second planarization layer 92 reduces step heights formed by the source electrode 65, the drain electrode 66 and the inorganic layer 91. When the thickness of the metal wirings such as the source electrode 65 and/or the drain electrode 66 is increased to reduce the RC delay, a step height between the source electrode 65 and/or the drain electrode 66, and subsequent layers, may increase. Therefore, the second planarization layer 92 is needed to correct or reduce the step height. For the second planarization layer 92 to correct the step height, a maximum distance between a surface of the substrate 10 and a top surface of the second planarization layer 92 may be smaller than or equal to a maximum distance between the surface of the substrate 10 and a top surface of the second inorganic layer 91.

The second planarization layer 92 may be an organic layer including an organic material. An organic layer has better planarization properties than an inorganic material. Therefore, even when a metal wiring has a relatively large thickness, the second planarization layer 92 including an organic material can easily improve step height characteristics of the metal wiring. Specifically, the organic material may include a material or a mixture of materials selected from the group consisting of acryl, polyimide, and polyacrylimide. However, the present invention is not limited thereto, and any material known in the art can be used without impairing the objectives of the present invention.

The second insulating layer 93 may be on an entire surface of the substrate 10 to cover the inorganic layer 91 and the planarization layer 92. The second insulating layer 93 may include an inorganic material, such as silicon nitride or silicon oxide, or a low-k insulating material formed by PECVD, such as a-Si:C:O or a-Si:O:F.

As described above, a TFT according to exemplary embodiments of the present invention includes a thick low resistance wiring including copper or copper alloy. Thus, the RC delay can be reduced. In addition, the diffusion of copper can be reduced or effectively prevented by an inorganic layer that surrounds the metal wiring. Furthermore, a planarization layer included in the TFT can reduce or effectively prevent a short circuit due to a step height even when the metal wiring has a relatively large thickness.

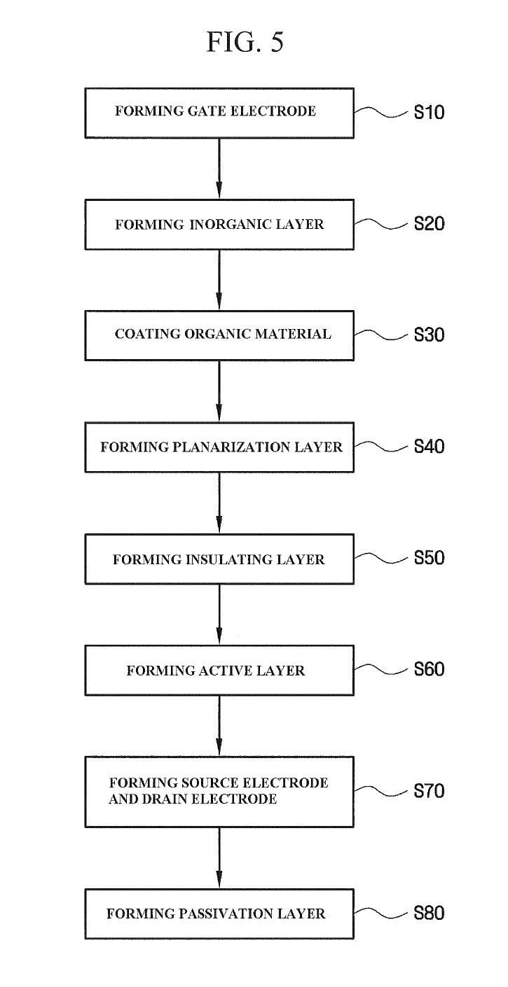

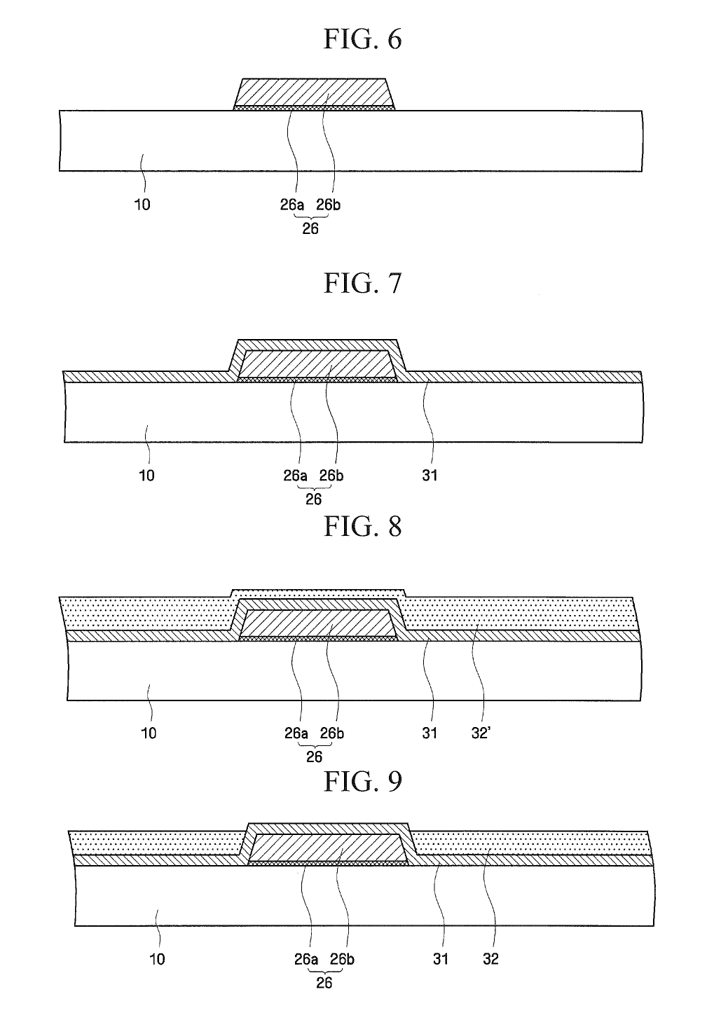

Hereinafter, an exemplary embodiment of a method of manufacturing a TFT substrate according to the present invention will be described with reference to FIGS. 5 through 13. FIG. 5 is a flowchart illustrating the exemplary embodiment of the method of manufacturing a TFT substrate according to the present invention. FIGS. 6 through 13 are cross-sectional views respectively illustrating exemplary embodiments of processes of the method of manufacturing a TFT substrate according to the present invention.

Referring to FIG. 5, the method of manufacturing a TFT substrate includes forming a gate electrode (operation S10), forming an inorganic layer (operation S20), coating an organic material (operation S30), forming a planarization layer (operation S40), forming an insulating layer (operation S50), forming an active layer (operation S60), forming a source electrode and a drain electrode (operation S70), and forming a passivation layer (operation S70).

In the method of manufacturing a TFT substrate according to the illustrated exemplary embodiment, the inorganic layer is formed to reduce or effectively prevent the diffusion of a gate electrode material, and the planarization layer is formed to reduce or effectively prevent a short circuit due to a step height even when the gate electrode is formed to have a relatively large thickness. In the illustrated exemplary embodiment, the gate electrode is used as an example of a wiring. However, the present invention can apply to all cases where a metal wiring is formed, as well as to a case where the source electrode and the drain electrode are formed.

Referring to FIG. 6, the gate electrode 26 is formed on the substrate 10, in the forming of the gate electrode (operation S10).

Specifically, a metal layer is formed directly on the upper surface of the substrate 10 such as by sputtering or plating, and is patterned such as by a photolithography process to form the gate electrode 26. The substrate 10 may be an insulating substrate including, for example, glass, quartz, or plastic. The metal layer may include aluminum-based metal such as aluminum or an aluminum alloy, silver-based metal such as silver or a silver alloy, copper-based metal such as copper or a copper alloy, molybdenum-based metal, such as molybdenum or a molybdenum alloy, chrome, titanium or tantalum. As shown in FIG. 6, the gate electrode 26 may include the upper copper layer 26b including copper or a copper alloy, and the titanium lower layer 26a disposed between the copper layer 26b and the substrate 10, and including titanium that exhibits better contact characteristics than copper.

The gate electrode 26 may be formed to the thickness of at least about 5,000 Å such that the resistance of the gate electrode 26 is reduced to decrease the RC delay.

Referring to FIG. 7, the first inorganic layer 31 is formed directly on the gate electrode 26 to surround the gate electrode 26, in the forming of the inorganic layer (operation S20).

Specifically, the first inorganic layer 31 is formed by depositing an inorganic material, such as silicon oxide or silicon nitride, using, e.g., PECVD.

As shown in FIG. 7, the first inorganic layer 31 may not only directly surround the gate electrode 26, but also extend onto the portion of the upper surface of the substrate 10 not overlapped by the gate electrode 26. Alternatively, the first inorganic layer 31 may surround the gate electrode 26, but may not extend onto the portion of the upper surface of the substrate 10 on which the gate electrode 26 is not formed. Also, the first inorganic layer 31 may be formed in direct contact with the gate electrode 26.

The first inorganic layer 31 may be formed to the thickness of about 200 Å to about 5,000 Å, and if possible, about 1,000 Å to about 5,000 Å. In the above thickness range, the first inorganic layer 31 can reduce or effectively prevent the diffusion of copper when the gate electrode 26 includes copper.

Referring to FIG. 8, an organic material is coated on the first inorganic layer 31, in the coating of the organic material (operation S30), thereby forming an organic layer 32′. If the first inorganic layer 31 surrounds the gate electrode 26 but does not extend onto the substrate 10, the organic material may be coated directly on both the substrate 10 and the first inorganic layer 31.

Specifically, the organic layer 32′ is formed on the first inorganic layer 31 by a coating process in which a coating solution obtained by dissolving an organic material in a solvent is coated on the first inorganic layer 31, and then the solvent is volatilized. The organic material may be, but is not limited to, acrylic resin, polyimide, or polyacrylamide. The coating process may be any coating process known in the art, such as spin coating, slit coating, or spray coating.

The organic material may be coated to have a portion at a height above a top surface of the first inorganic layer 31 overlapping the gate electrode 26 from the substrate 10, or to have a portion at a height above at least a top surface of the gate electrode 26 from the substrate 10. Accordingly, empty spaces on sides of the gate electrode 26 and sides of the first inorganic layer 31 are filled in with the organic material.

Referring to FIG. 9, a predetermined region of an upper part of the organic layer 32′ is removed in the forming of the planarization layer (operation S40), such that the height of the organic layer 32′ formed in the coating of the organic material (operation S30) becomes lower than a height of the portion of the first inorganic layer 31 overlapping the gate electrode 26. That is, an upper part of the organic layer 32′ is removed by a predetermined thickness such that a maximum distance between a surface of the substrate 10 and a top surface of the organic layer 32′ is smaller than or equal to a maximum distance between the surface of the substrate 10 and a top surface of the first inorganic layer 31.

Specifically, the height of the organic layer 32′ may be reduced by performing an ashing process on the upper part of the organic layer 32′ formed in the coating of the organic material (operation S30). The ashing process may be performed using any conventional method known in the art, such as oxygen (O₂) plasma ashing or ozone ashing.

When the gate electrode 26 is formed to the thickness of at least about 5,000 Å in order to realize a low resistance wiring, its step height is increased, which, in turn, deteriorates step height characteristics thereof. That is, an insulating layer formed on the gate electrode 26 may have an uneven surface with a large step height and thus may result in short-circuit. In the method of manufacturing a TFT substrate according to the illustrated exemplary embodiment, the first planarization layer 32 is formed to improve the step height characteristics when the metal wiring is formed to have a relatively large thickness. Since the first planarization layer 32 is designed to reduce the step height of the gate electrode 26 and/or the first inorganic layer 31, the first planarization layer 32 may be formed to a height not greater than the height of the first inorganic layer 31 on the gate electrode 26.

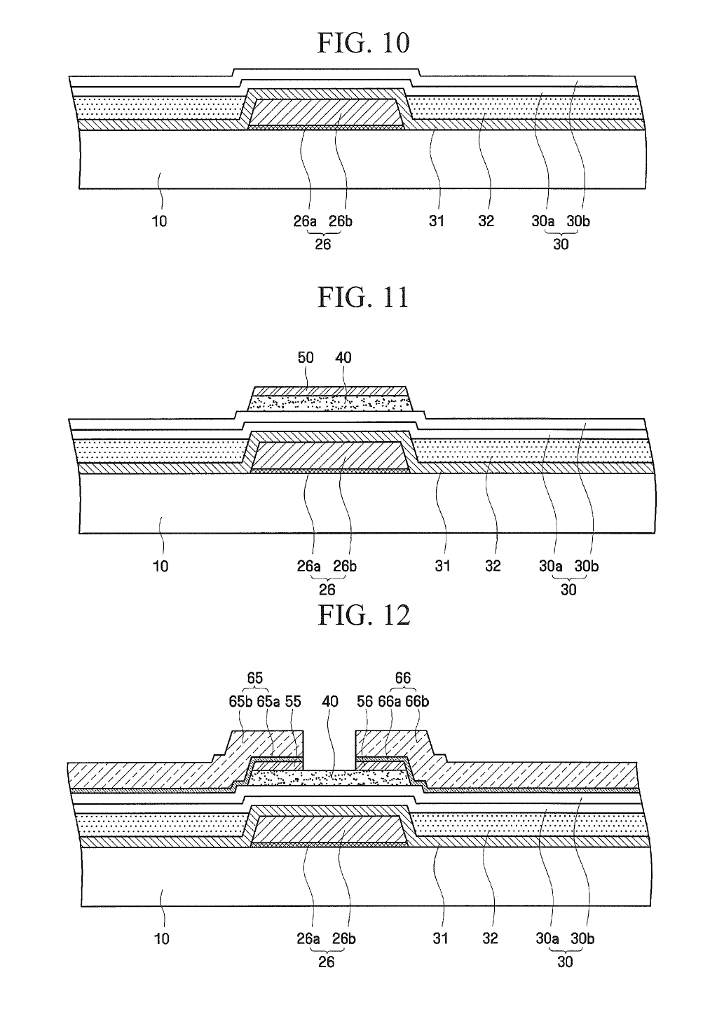

Referring to FIG. 10, the first insulating layer 30 is formed directly on the first inorganic layer 31 and on the first planarization layer 32, in the forming of the insulating layer (operation S50).

The first insulating layer 30 may include the first insulating sub-layer 30a formed directly on the first inorganic layer 31 and the first planarization layer 32, and the second insulating sub-layer 30b formed directly on the first insulating sub-layer 30a.

Specifically, the first insulating sub-layer 30a may be formed by depositing an inorganic material, such as silicon nitride or silicon oxide, or an organic material having photosensitivity and superior planarization characteristics on the first inorganic layer 31 and the first planarization layer 32 at first speed using PECVD. Then, the second insulating sub-layer 30b may be formed by depositing an inorganic material, such as silicon nitride or silicon oxide, or an organic material having photosensitivity and superior planarization characteristics on the first insulating sub-layer 30a at second speed, which is higher than the first speed, using chemical vapor deposition (“CVD”). By varying the deposition speed as described above, properties of the second insulating sub-layer 30b can be enhanced over those of the first insulating sub-layer 30a.

Referring to FIG. 11, the active layer 40 is formed by sequentially stacking a polycrystalline or amorphous silicon layer and a doped amorphous silicon layer directly on the second insulating sub-layer 30b, and patterning the stacked polycrystalline or amorphous silicon layer and the doped amorphous silicon layer, in the forming of the active layer (operation S60).

Specifically, a polycrystalline or amorphous silicon layer and a doped amorphous silicon layer are sequentially stacked directly on the second insulating sub-layer 30b by, e.g., PECVD. Then, a photosensitive layer is formed on the doped amorphous silicon layer and is exposed to light, thereby forming a photosensitive pattern. Next, the polycrystalline or amorphous silicon layer and the doped amorphous silicon layer are etched to form the island-shaped active layer 40 and a doped amorphous silicon layer pattern 50. The etching process may be performed using a conventional method known in the art, such as dry etching.

Referring to FIG. 12, the ohmic contact layers 55 and 56, the source electrode 65 and the drain electrode 66 are formed on the active layer 40, in the forming of the source electrode and the drain electrode (operation S70).

Specifically, a metal layer is formed directly on the doped amorphous silicon layer pattern 50 by, e.g., sputtering. Then, a photosensitive layer is coated on the metal layer and is exposed to light, thereby forming a photosensitive pattern. Next, the metal layer is etched to form the source electrode 65 and the drain electrode 66. After the source electrode 65 and the drain electrode 66 are formed, an exposed portion of the doped amorphous silicon layer pattern 50 is etched to form the ohmic contact layers 55 and 56 which are separated from each other with respect to the gate electrode 26, and to expose a portion of the active layer 40 between the ohmic contact layers 55 and 56. Oxygen plasma ashing may be performed in order to stabilize a surface of the exposed portion of the active layer 40. The etching process may be performed using any method known in the art.

The metal layer may include chrome, molybdenum-based metal, or refractory metal such as tantalum or titanium. In addition, the metal layer may have a multi-layer structure including a lower layer (not shown), which is formed of refractory metal, and an upper layer (not shown), which is formed of a material with low resistance and is disposed on the lower layer. As shown in FIG. 12, the metal layer may include upper copper layers 65b and 66b including copper or a copper alloy to reduce resistance, and lower titanium layers 65a and 66a disposed between the upper copper layers 65b and 66b and the ohmic contact layers 55 and 56, respectively, and including titanium that exhibits better contact characteristics than copper. In addition, the metal layer may be formed to the thickness of about 5,000 Å or more in order to realize a low resistance wiring.

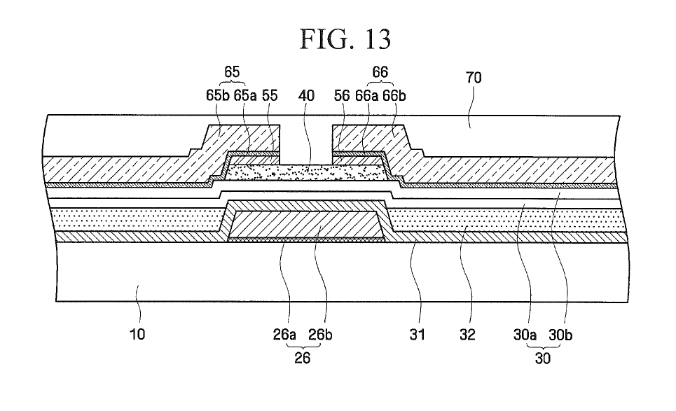

Referring to FIG. 13, the passivation layer 70 is formed directly on the source electrode 65, the drain electrode 66, and the active layer 40, in the forming of the passivation layer (operation S80).

Specifically, the passivation layer 70 may be formed by depositing an inorganic material such as silicon nitride or a low-k insulating material such as a-Si:O:F on the source electrode 65, the drain electrode 66, and the exposed portion of the active layer 40 using PECVD.

When the source electrode 65 and the drain electrode 66 include copper, the passivation layer 70 may include an inorganic material. The passivation layer 70 includes an inorganic material because when the passivation layer 70 is an inorganic layer including an inorganic material, it can reduce or effectively prevent the diffusion of copper. The passivation layer 70 is formed to have an even planar upper surface without a step. Thus, no additional planarization layer may be required.

As described above, the exemplary embodiment of the method of manufacturing a TFT substrate according to the present invention can be used to manufacture a TFT in which the diffusion of copper does not occur even when a low resistance wiring including copper, and in which a short circuit due to a step height does not occur even when the wiring is relatively thick.

In exemplary embodiments of a TFT substrate according to the present invention, when a metal wiring includes copper, the diffusion of the copper can be reduced or effectively prevented. Therefore, a low resistance wiring can be formed using copper, and thus the RC delay of a liquid crystal display can be reduced.

Exemplary embodiments of a TFT substrate according to the present invention include a planarization layer that can reduce or effectively prevent a short circuit between a source electrode and a drain electrode even when a low resistance wiring includes a thick metal layer. Since the planarization layer allows the thickness of a metal layer to be increased in the process of forming a metal wiring, a low resistance wiring can be realized.

However, the effects of the present invention are not restricted to the one set forth herein. The above and other effects of the present invention will become more apparent to one of daily skill in the art to which the present invention pertains by referencing the claims.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A thin-film transistor substrate comprising:
a metal wiring including copper or a copper alloy on a substrate;
an inorganic layer on an upper surface and side surfaces of the metal wiring to surround the metal wiring, and in direct contact with the metal wiring; and
a planarization layer on the inorganic layer and in direct contact with the inorganic layer.

2. The thin-film transistor substrate of claim 1, wherein the metal wiring is a gate electrode, a source electrode, or a drain electrode.

3. The thin-film transistor substrate of claim 1, wherein the planarization layer includes an organic material.

4. The thin-film transistor substrate of claim 1, wherein the inorganic layer includes silicon nitride (SiNx).

5. The thin-film transistor substrate of claim 1, wherein a maximum distance between a surface of the substrate and a top surface of the planarization layer, is equal to or smaller than a maximum distance between the surface of the substrate and a top surface of the inorganic layer.

6. The thin-film transistor substrate of claim 1, wherein
the metal wiring is a gate electrode, and
the gate electrode has a thickness of about 5,000 angstroms (Å) or more.

7. The thin-film transistor substrate of claim 1, wherein
the metal wiring is a gate electrode, and
the inorganic layer surrounds the gate electrode, and contacts a portion of the substrate excluding the gate electrode.

8. The thin-film transistor substrate of claim 1,
wherein the metal wiring is a gate electrode, and
further comprising:
an active layer on the inorganic layer, the active layer overlapping the gate electrode;
ohmic contact layers on the active layer and separated from each other with respect to the active layer; and
a source electrode and a drain electrode including copper or a copper alloy, on the ohmic contact layers.

9. The thin-film transistor substrate of claim 8, wherein the drain electrode and the source electrode have a thickness of about 5,000 angstroms (Å) or more.

10. The thin-film transistor substrate of claim 9, further comprising a passivation layer including an inorganic material on the source electrode and the drain electrode, wherein the passivation layer is in contact with the source electrode and in contact with the drain electrode.

11. The thin-film transistor substrate of claim 1, further comprising an insulating layer on an entire surface of the substrate, and covering the inorganic layer and the planarization layer.

12. A method of manufacturing a thin-film transistor substrate, the method comprising:
forming a metal wiring including copper or a copper alloy on a substrate;
forming an inorganic layer in direct contact with an upper surface and side surfaces of the metal wiring, to surround the metal wiring;
forming an organic layer including an organic material, on the substrate; and
planarizing the organic layer by removing a predetermined portion of the organic layer, such that a maximum distance between a surface of the substrate and a top surface of the organic layer is smaller than or equal to a maximum distance between the surface of the substrate and a top surface of the inorganic layer.

13. The method of claim 12, wherein the metal wiring is formed to a thickness of about 5,000 angstroms (Å) or more.

14. The method of claim 12, wherein in the planarizing the organic layer, an upper part of the organic layer is removed by a predetermined thickness using an ashing process.

15. The method of claim 12, wherein
the metal wiring is a gate electrode; and
the organic material is coated on the substrate such that a top surface of the organic layer is higher than a top surface of the gate electrode.

16. The method of claim 12, wherein the organic layer is formed including the organic material, by a coating process.

17. The method of claim 12, wherein the metal wiring is a gate electrode, a source electrode, or a drain electrode.

18. A thin-film transistor substrate comprising:
a first metal wiring including copper or a copper alloy on a substrate, wherein the first metal wiring has an upper surface at a maximum thickness of the first metal wiring;
a first inorganic layer contacting the upper surface and contacting side surfaces of the first metal wiring; and
a first organic layer contacting the first inorganic layer, wherein an upper surface of the first organic layer is closer to the substrate than an upper surface of the first inorganic layer overlapping the upper surface of the first wiring.

19. The thin-film transistor substrate of claim 18,
further comprising:
a second metal wiring including copper or a copper alloy on the substrate, wherein the second metal wiring has an upper surface at a maximum thickness of the second metal wiring;
a second inorganic layer contacting the upper surface and contacting side surfaces of the second metal wiring; and
a second organic layer contacting the second inorganic layer, wherein an upper surface of the second organic layer is closer to the substrate than an upper surface of the second inorganic layer overlapping the upper surface of the second wiring; and
further comprising an insulting layer between and contacting both the second metal wiring and the first organic layer.

20. The thin-film transistor substrate of claim 19, wherein
the first metal wiring is a gate electrode, and
the second metal wiring is a source electrode and a drain electrode.
